(19) United States
(12) Patent Application Publication
(10) Pub. No.: US 2016/0071942 A1
(43) Pub. Date: Mar. 10, 2016

(54) SEMICONDUCTOR MEMORY

(71) Applicant: KABUSHIKI KAISHA TOSHIBA, Tokyo (JP)

(72) Inventors: Daisuke IKENO, Yokkaichi (JP); Atsuko SAKATA, Yokkaichi (JP)

(73) Assignee: KABUSHIKI KAISHA TOSHIBA

(21) Appl. No.: 14/633,229

(22) Filed: Feb. 27, 2015

Related U.S. Application Data
(60) Provisional application No. 62/046,323, filed on Sep. 5, 2014.

(51) Int. Cl. H01L 29/423; H01L 27/115; H01L 29/49; H01L 29/788

(52) U.S. Cl. CPC H01L 29/42332; H01L 29/788; H01L 27/11521; H01L 29/4975

(57) ABSTRACT

According to an embodiment, a semiconductor memory device includes a semiconductor substrate, a first insulating layer, a first floating gate, a second insulating layer, a second floating gate, a third insulating layer, and a control gate. The first insulating layer is provided on the semiconductor substrate. The first floating gate is provided on the first insulating layer. The first floating gate includes silicon. The second insulating layer is provided on the first floating gate. The second floating gate is provided on the second insulating layer. The second floating gate includes ruthenium suicide containing not less than 50 atm % Ru. The third insulating layer is provided on the second floating gate. The control gate is provided on the third insulating layer.

### CROSS-REFERENCE TO RELATED APPLICATIONS

This application is based upon and claims the benefit of priority from U.S. Provisional Patent Application 62/046,323, filed on Sep. 5, 2014; the entire contents of which are incorporated herein by reference.

### FIELD

Embodiments described herein relate generally to a semiconductor memory.

### BACKGROUND

For example, NAND flash memory is being developed as a nonvolatile semiconductor memory device. In NAND flash memory, a floating gate is provided on a substrate with a tunneling insulating layer interposed. The storage of information is performed by controlling the storage or non-storage of charge in the floating gate.

Technology that stores charge stably in the floating gate is desirable for NAND flash memory.

### BRIEF DESCRIPTION OF THE DRAWINGS

FIG. 1 is a plan view of a semiconductor memory device 1 according to the first embodiment;

FIG. 2A is an A-A cross-sectional view of FIG. 1; and FIG. 2B is a B-B cross-sectional view of FIG. 1;

FIGS. 3A to 3D are cross-sectional views of processes, showing the manufacturing process of the semiconductor memory device 1 according to the first embodiment;

FIG. 4 is a conceptual view showing the work functions of the metal layers and semiconductor layers and the electron barriers of the insulating film layers for the semiconductor memory device 1 according to the first embodiment;

FIG. 5A is a figure showing the relationship between a flat band voltage (V_{fb}) and the SiO₂ film equivalent film thickness (EOT) of a capacitor using a RuSiₓ film; and FIG. 5B is a figure showing the relationship between V_{fb} and the composition of RuSiₓ for the capacitor using the RuSiₓ film;

FIG. 6 is a plan view of a semiconductor memory device 2 according to the second embodiment; and

FIG. 7A is an A-A cross-sectional view of FIG. 6; and FIG. 7B is a B-B cross-sectional view of FIG. 6.

### DETAILED DESCRIPTION

According to an embodiment, a semiconductor memory device includes a semiconductor substrate, a first insulating layer, a first floating gate, a second insulating layer, a second floating gate, a third insulating layer, and a control gate. The first insulating layer is provided on the semiconductor substrate. The first floating gate is provided on the first insulating layer. The first floating gate includes silicon. The second insulating layer is provided on the first floating gate. The second floating gate is provided on the second insulating layer. The second floating gate includes ruthenium silicide containing not less than 50 atm % Ru. The third insulating layer is provided on the second floating gate. The control gate is provided on the third insulating layer.

Embodiments of the invention will now be described with reference to the drawings.

The drawings are schematic; and the relationships between the thicknesses and widths of portions, the proportions of sizes between portions, etc., are not necessarily the same as the actual values thereof. Also, the dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

### First Embodiment

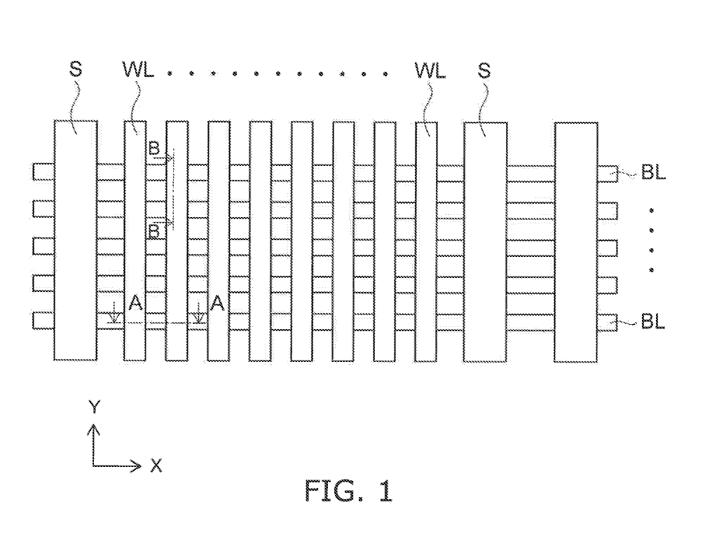

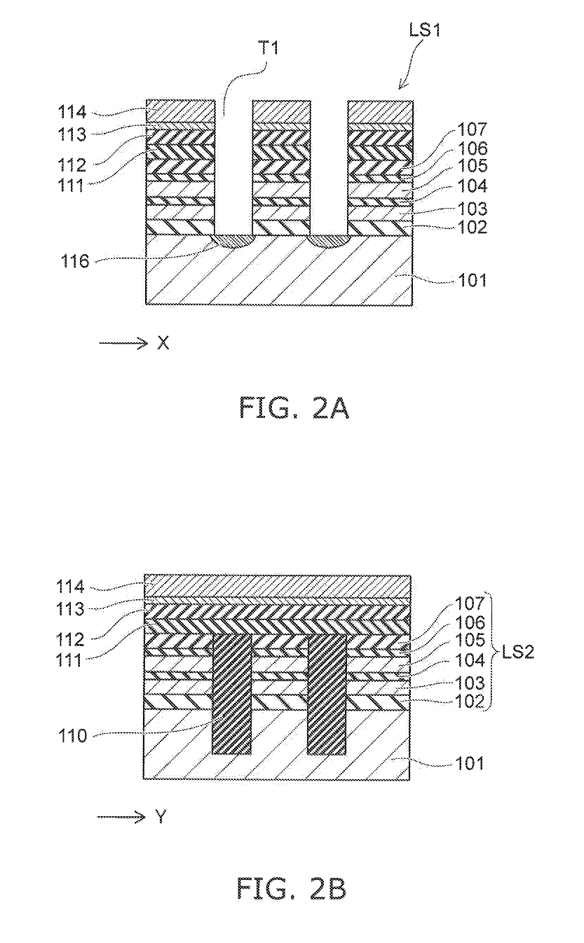

A first embodiment will be described using FIG. 1 and FIG. 2.

FIG. 1 is a plan view of a semiconductor memory device 1 according to the first embodiment.

FIG. 2 shows cross-sectional views of portions of the semiconductor memory device 1 according to the first embodiment.

FIG. 2A is an A-A cross-sectional view of FIG. 1.

FIG. 2B is a B-B cross-sectional view of FIG. 1.

The semiconductor memory device 1 is, for example, NAND flash memory.

As shown in FIG. 1, the semiconductor memory device 1 includes multiple bit lines BL, multiple word lines WL, and a selection line S. The bit lines BL extend along an X-direction (a first direction). The word lines WL extend along a V-direction (a second direction) orthogonal to the X-direction.

Memory cell transistors are provided at the intersections between the bit lines BL and the word lines WL. The memory cell transistors are electrically connected to the bit lines BL and the word lines WL.

Selection transistors are provided at the intersections between the selection line S and the bit lines BL. The selection transistors are electrically connected to the selection line S and the bit lines BL.

First, the semiconductor memory device 1 will be described using FIG. 2A.

The semiconductor memory device 1 includes a substrate 101. The substrate 101 is, for example, a monocrystalline Si substrate in which at least the upper layer portion is the P-type.

A tunneling insulating layer 102 is provided on the substrate 101. The tunneling insulating layer 102 is, for example, a SiO₂ layer. Other than SiO₂, it is possible to use SiON, SIN, etc., as the material of the tunneling insulating layer 102.

A first floating gate 103 is provided on the tunneling insulating layer 102. The first floating gate 103 includes silicon. The first floating gate 103 is, for example, non-doped polycrystalline silicon. Polycrystalline silicon that is included in a first floating gate 103 may be doped with an N-type or P-type impurity.

An IFD (Inter Floating gate Dielectric) layer 104 is provided on the first floating gate 103. The IFD layer 104 is, for example, a SiN layer.

A second floating gate 105 is provided on the IFD layer 104. The second floating gate 105 includes RuSiₓ (ruthenium silicide). The second floating gate 105 is separated from the first floating gate 103 by the IFD layer 104. Thereby, the movement into the first floating gate 103 of the charge that is stored in the second floating gate 105 can be suppressed.

A barrier layer 106 is provided on the second floating gate 105. The barrier layer 106 is, for example, a SiN layer.

A first IPD (Inter Poly-Si Dielectric) layer 107 is provided on the barrier layer 106. The IPD layer 107 is, for example, a HfOₓ layer. By providing the barrier layer 106, the oxidization of the RuSiₓ layer which is the second floating gate 105 by the oxygen included in the HfOₓ layer which is the first IPD layer 107 can be suppressed.

A second IPD layer 111 is provided on the first IPD layer 107. The IPD layer 111 is, for example, a SiO₂ layer,

A third IPD layer 112 is provided on the second IPD layer 111. The third IPD layer 112 is, for example, a HfOₓ layer.

A barrier metal layer 113 is provided on the third IPD layer 112. The barrier metal layer 113 is, for example, a WN layer.

A control gate 114 is provided on the barrier metal layer 113. The control gate 114 is, for example, a W layer. Other than W, it is possible to use polycrystalline silicon, a silicide including Ni, a silicide including Co, etc., as the material of the control gate 114. The barrier metal layer 113 suppresses the diffusion of the metal atoms included in the control gate 114.

A stacked structure LS1 (a second stacked structure) that includes the tunneling insulating layer 102 to the control gate 114 is multiply provided in the X-direction. The stacked structures LS1 are separated from each other by a trench T1 extending in the Y-direction.

A semiconductor region 116 that is the N-type is provided in the region of the substrate 101 where the trench T1 is provided.

The semiconductor memory device 1 will now be described using FIG. 2B.

As described in FIG. 2A, the tunneling insulating layer 102 to the control gate 114 are provided on the substrate 101.

A stacked structure LS2 that includes the tunneling insulating layer 102 to the first IPD layer 107 is multiply provided in the Y-direction. The stacked structures LS2 (first stacked structures) are separated from each other by a separation region 110 extending in the X-direction.

The second IPD layer 111 to the control gate 114 are provided to be flat on the multiple stacked structures LS2 and on the separation region 110. In other words, the second IPD layer 111 to the control gate 114 are provided commonly for the multiple stacked structures LS2.

The separation region 110 is, for example, a SiO₂ layer.

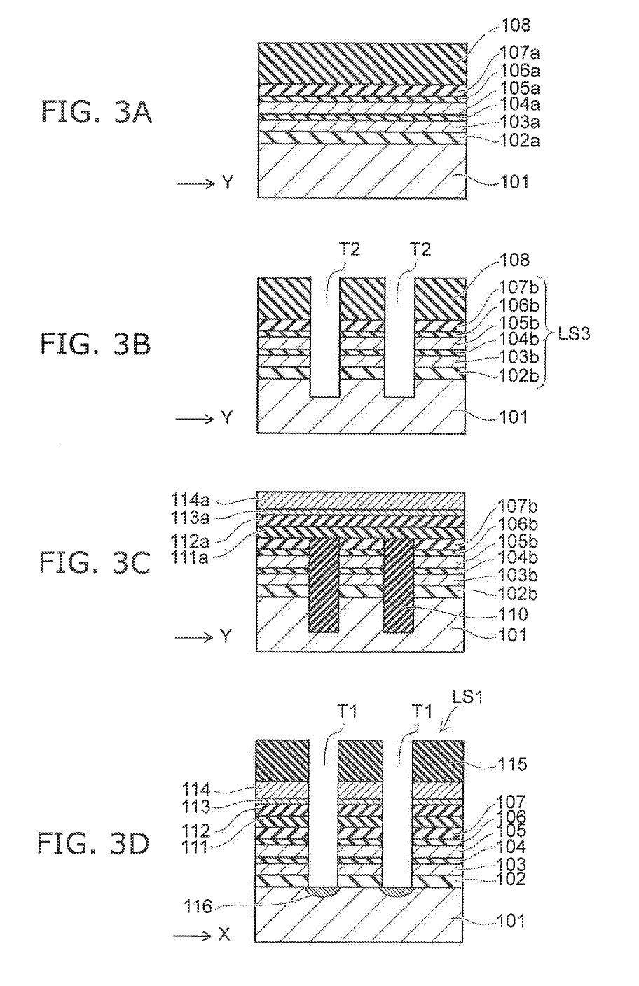

A method for manufacturing the semiconductor memory device 1 will now be described using FIG. 3.

FIG. 3 shows cross-sectional views of processes, showing the manufacturing process of the semiconductor memory device 1 according to the first embodiment.

FIGS. 3A to 3C show a cross section of the semiconductor memory device 1 in the Y-direction; and FIG. 3D shows a cross section of the semiconductor memory device 1 in the X-direction.

A tunneling insulating film 102a is formed on the monocrystalline Si substrate 101 by, for example, depositing a SiO₂, film having a thickness of 6 nm by thermal oxidation.

A first floating gate film 103a is formed on the tunneling insulating film 102a by, for example, depositing a polycrystalline silicon film having a thickness of 6 nm with an impurity by CVD. The impurity is, for example, B (boron). However, the polycrystalline silicon film may not contain an impurity.

An IFD film 104a is formed on the first floating gate film 103a by, for example, depositing a SiN film having a thickness of 2 nm by ALD.

A second floating gate film 105a is formed on the IFD film 104a by, for example, depositing a RuSiₓ film having a thickness of 5 nm by PVD. The RuSiₓ film includes RuSiₓ containing not less than 50% Ru. The RuSiₓ film is formed by, for example, sputtering a target made of RuSiₓ containing not less than 50% Ru. Or, the RuSiₓ film is formed by simultaneously sputtering a target of Ru and a target of Si. At this time, the RuSiₓ film that contains not less than 50% Ru is formed by adjusting the sputter rate for each target. The details of the RuSiₓ according to the embodiment are described below.

A barrier film 106a is formed on the second floating gate film 105a by, for example, depositing a SiN film having a thickness of 2 nm by ALD.

For example, a HfOₓ film having a thickness of 5 nm is deposited on the barrier film 106a by CVD. Then, a first IPD film 107a is formed by performing heat treatment of the HfOₓ film at about 900° C.

A hard mask 108 that is made of, for example, SiO₂ is formed on the first IPD film 107a.

The appearance at this time is shown in FIG. 3A.

The hard mask 108 is patterned by photolithography and RIE.

The tunneling insulating film 102a to the first IPD film 107a are patterned by RIE using the patterned hard mask 108. Thereby, a tunneling insulating layer 102b to a first IPD layer 107b are formed. At this time, a trench T2 that extends in the X-direction is made between stacked structures LS3 including the tunneling insulating layer 102b to the first IPD layer 107b. The stacked structures LS3 are separated from each other in the Y-direction by the trench T2.

The appearance at this time is shown in FIG. 3B.

The trench T2 is filled by, for example, depositing SiO₂ by CVD.

The front surface is planarized by removing the excess SiO₂ existing on the front surface by CMP.

The hard mask 108 is removed. Thereby, the separation region 110 that is provided inside the trench T2 is formed.

A second IPD film 111a is formed on the first IPD layer 107b and on the separation region 110 by, for example, depositing a SiO₂ film having a thickness of 5 nm by ALD.

For example, a HfOₓ film that has a thickness of 5 nm is deposited on the second IPD film 111a by CVD. Then, a third IPD film 112a is formed by performing heat treatment of the HfOₓ film at about 900° C.

A barrier metal film 113a is formed on the third IPD film 112a by, for example, depositing a WN film by PVD.

A control gate 114a is formed on the barrier metal film 113a by, for example, depositing a W film by PVD.

A hard mask 115 that is made of SiO₂ is formed on the control gate 114a.

The appearance at this time is shown in FIG. 3C.

The hard mask 115 is patterned by photolithography and RIE.

The tunneling insulating layer 102b to the first IPD layer 107b and the second IPD film 111a to the control gate 114a are patterned by RIE using the patterned hard mask 115. Thereby, the tunneling insulating layer 102 to the control gate 114 are formed. At this time, the trench T1 that extends in the Y-direction is made between the stacked structures LS1 including the tunneling insulating layer 102 to the control gate 114. The stacked structures LS1 are separated from each other in the X-direction by the trench T1.

The N-type semiconductor region 116 is formed at the bottom portion of the trench T1 by performing ion implantation and heat treatment of the substrate 101 using the hard mask 115 as a mask.

The appearance at this time is shown in FIG. 3D.

Finally, the semiconductor memory device 1 according to the embodiment is obtained by removing the hard mask 115.

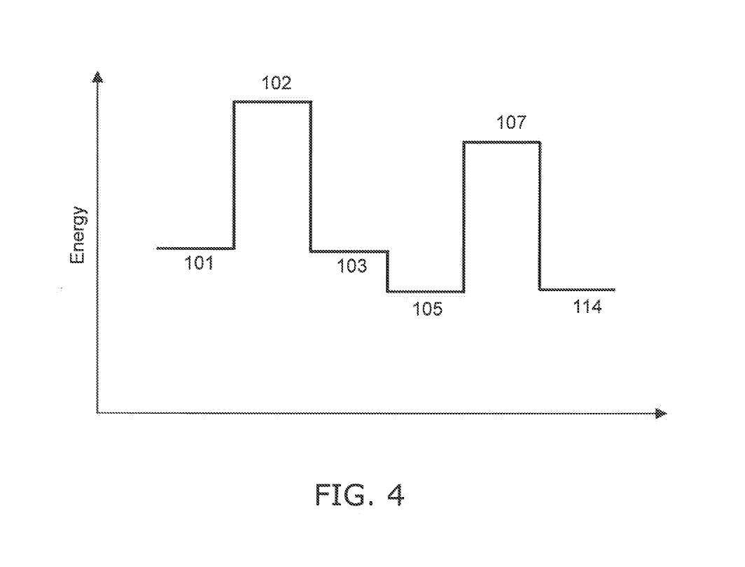

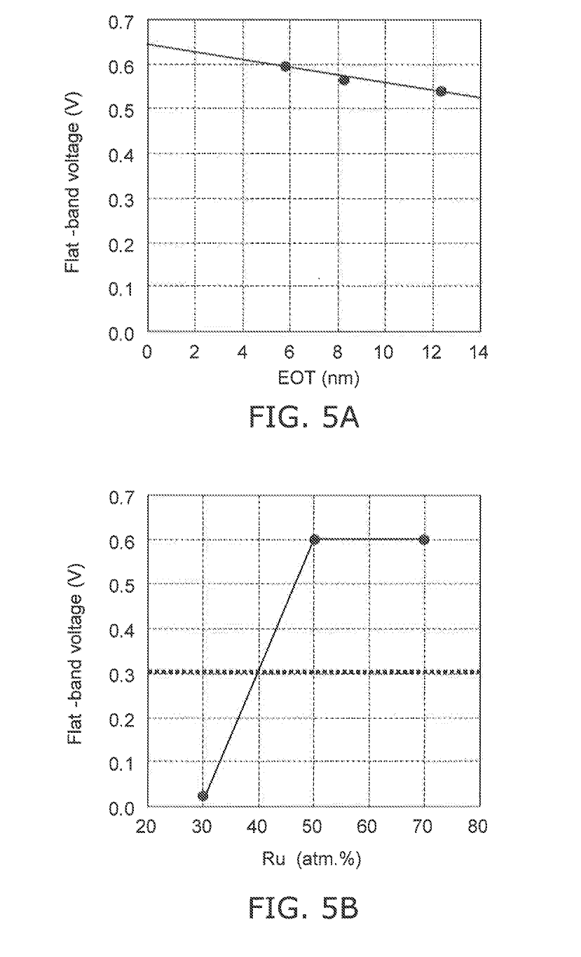

Details of the second floating gate 105 will be described using FIG. 4 and FIG. 5.

FIG. 4 is a conceptual view showing the work functions of the metal layers and semiconductor layers and the electron barriers of the insulating film layers for the semiconductor memory device 1 according to the first embodiment.

FIG. 5A is a figure showing the relationship between a flat band voltage (V_{fb}) and the SiO₂ film equivalent film thickness (EOT) of a capacitor using a RuSiₓ film.

FIG. 5B is a figure showing the relationship between V_{fb} and the composition of the RuSiₓ film for the capacitor using the RuSiₓ film.

In FIG. 4, the horizontal axis is the position in a normal direction of the substrate 101 front surface; and the vertical axis is the energy value at each position. FIG. 4 shows only the work functions and electron barriers of some of the layers of the semiconductor memory device 1. As an example in FIG. 4, for easier understanding of the description of the relative relationship between the work function value of the first floating gate 103 and the work function value of the second floating gate 105, the electron barrier of the IFD layer 104 is omitted; and the work function of the first floating gate 103 and the work function of the second floating gate 105 are shown as being connected. The energy value of the work function and the energy value of the electron barrier for each layer shown on the vertical axis of FIG. 4 are relative and do not represent absolute values. Similarly, the positions of each layer shown on the horizontal axis of FIG. 4 are relative and do not represent the absolute positions and film thicknesses of each layer.

As shown in FIG. 4, in the case where the work function value of the second floating gate 105 is greater than the work function value of the first floating gate 103, the electron barrier of the first IPD layer 107 on the floating gate side increases by the amount of the difference between the work function value of the first floating gate 103 and the work function value of the second floating gate 105. Therefore, the movement of the electrons from the floating gate to the control gate 114 for the same applied voltage is suppressed; and the stored amount of the charge can be increased.

Experimental results relating to the embodiment will now be described using FIG. 5.

The experiment was performed by measuring the capacitance and voltage of a MOS capacitor using a metal electrode made of a RuSiₓ layer and a gate insulation layer made of a SiO₂ layer.

FIG. 5A is a figure showing the relationship between EOT and V_{fb} obtained by the measurement using a RuSiₓ layer including RuSiₓ containing 50 atm % Ru. In FIG. 5A, the horizontal axis is EOT; and the vertical axis is V_{fb}.

Each point inside FIG. 5A shows a value obtained from the experiment. It can be seen from a section of the straight line connecting these points that V_{fb} is 0.64 V when EOT is 0 nm.

The relationship between EOT and V_{fb}, is expressed as Formula (1) recited below.

$$Vfb = ( {φ}_{m} - {φ}_{s} ) - \frac{{Q}_{fix}}{{ɛ}_{0} {ɛ}_{ox }} EOT \qquad ( 1 )$$

φₛ: Work function of Si

φₘ: Work function of the metal electrode

Q_{fix}: Fixed charge density inside the SiO₂ film

ε₀: Vacuum dielectric constant

εₒₓ: Relative dielectric constant of the SiO₂ film

The Si work function φₛ=4.28 eV that is estimated from the impurity concentration inside the Si substrate of the MOS capacitor, EOT=0 nm that is obtained from FIG. 5A, and V_{fb}=0.64 V that is obtained from FIG. 5A are substituted in Formula (1). As a result, 4.9 eV is obtained as substantially the value of φₘ (the work function value of the RuSiₓ layer).

FIG. 5B is a figure showing the change of V_{fb} when EOT is set to 5.8 nm and the proportion of the Ru in the RuSiₓ is changed. In FIG. 5B, the horizontal axis is the proportion of Ru in the RuSiₓ; and the vertical axis is V_{fb}.

Each point inside FIG. 5B shows a value obtained from the experiment. From the results shown in FIG. 5A, it can be seen that V_{fb} is about 0.6 V in the case where EOT=5.8 nm for the RuSiₓ having the proportion of Ru of 50 atm % for which the work function value of about 4.9 eV was obtained. Accordingly, V_{fb} is about 0.6 V which is substantially the same as in the case where the proportion of Ru is 50 atm %; and it can be seen that φₘ is substantially 4.9 eV even in the case where the proportion of Ru is 70 atm %. Here, in FIG. 5B, the broken line inside FIG. 5B illustrates the value of the midgap (4.6 eV) of the bandgap of Si as the work function value of a thin film of polycrystalline Si that is non-doped or has a low activation rate in the case where the work function value is 4.9 eV when V_{fb}=0.6 V. As shown in FIG. 5B, the work function value of the RuSiₓ layer falls below the midgap of the bandgap of Si when the proportion of Ru is 30 atm %.

From the results recited above, it can be seen that the work function value of the RuSiₓ layer exceeds 4.6 eV which is the midgap of the bandgap of Si used in the first floating gate 103 when the proportion of Ru inside the RuSiₓ is 50 atm % or more.

The operations and effects of the embodiment will now be described.

In the semiconductor memory device 1, compared to the case where only the first floating gate 103 is provided, it is possible to increase the stored charge amount for the same applied programming voltage by providing, in addition to the first floating gate 103 including the polycrystalline silicon layer, the second floating gate 105 including RuSiₓ containing not less than 50 atm % Ru.

By providing the first floating gate 103 including polycrystalline silicon between the tunneling insulating layer 102 and the second floating gate 105 including RuSiₓ, the diffusion of the metal atoms from the RuSiₓ layer into the tunneling insulating layer 102 or plasma damage to the tunneling insulating layer 102 in the sputtering film formation of the RuSiₓ film can be suppressed.

Also, by providing the IFD layer 104 between the first floating gate 103 and the second floating gate 105, reactions between the polycrystalline silicon included in the first floating gate 103 and the RuSiₓ included in the second floating gate 105 are suppressed; and the likelihood of loss of the function of the second floating gate 105 can be reduced.

RuSiₓ has not only a high work function value but also high thermal stability and high oxidation resistance. Therefore, a structure also is possible in which the barrier layer 106 for suppressing the reactions between the second floating gate 105 and the IPD layer 107 is not provided. In the case where there is no barrier layer 106, the film thickness between the second floating gate 105 and the control gate 114 is reduced; and it is possible to strengthen the electric field of the tunneling insulating layer 102.

### Second Embodiment

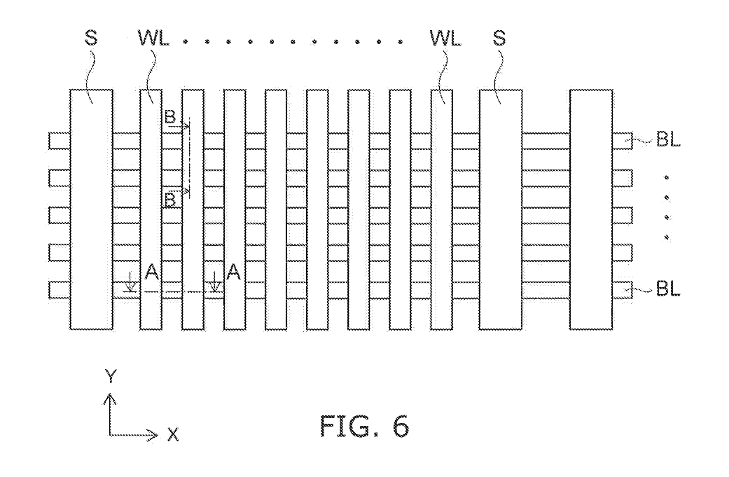

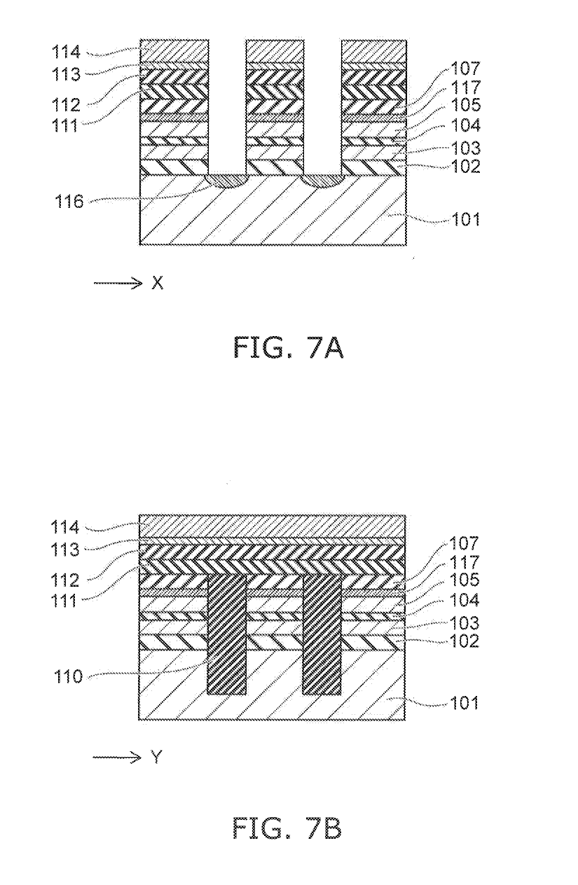

A second embodiment will be described using FIG. 6 and FIG. 7.

FIG. 6 is a plan view of a semiconductor memory device 2 according to the second embodiment.

FIG. 7 shows cross-sectional views of portions of the semiconductor memory device 2 according to the second embodiment.

FIG. 7A is an A-A cross-sectional view of FIG. 6.

FIG. 7B is a B-B cross-sectional view of FIG. 6.

As shown in FIG. 6, similarly to the semiconductor memory device 1, the semiconductor memory device 2 includes the multiple bit lines BL, the multiple word lines WL, and the selection line S.

As shown in FIG. 7, the semiconductor memory device 2 differs from the semiconductor memory device 1 in that the semiconductor memory device 2 includes a third floating gate 117 but does not include the barrier layer 106.

The third floating gate 117 includes, for example, a metal nitride such as TiN, TaN, etc.

The reactions of the oxygen atoms of the first IPD layer 107 with the RuSiₓ can be suppressed by providing the third floating gate 117 including a metal nitride having excellent oxidation resistance at the upper portion of the second floating gate 105 including the RuSiₓ.

It is possible to use a method similar to the method for manufacturing the semiconductor memory device 1 as the method for manufacturing the semiconductor memory device 2.

In the embodiment as well, similarly to the first embodiment, it is possible to stably store charge in the floating gate.

It is possible to measure the proportion of Ru contained in the RuSiₓ by, for example, secondary ion mass spectrometry, X-ray photoelectron spectroscopy, etc.

The stoichiometric ratios of the elements of the materials illustrated in the embodiments can be set to optimal values as appropriate unless otherwise noted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device, comprising:
a semiconductor substrate;
a first insulating layer provided on the semiconductor substrate;
a first floating gate provided on the first insulating layer, the first floating gate including silicon;
a second insulating layer provided on the first floating gate;
a second floating gate provided on the second insulating layer, the second floating gate including ruthenium silicide containing not less than 50 atm % Ru;
a third insulating layer provided on the second floating gate; and
a control gate provided on the third insulating layer.

2. The semiconductor memory device according to claim 1, wherein the first insulating layer is a silicon oxide layer.

3. The semiconductor memory device according to claim 1, wherein the second insulating layer is a silicon nitride layer.

4. The semiconductor memory device according to claim 1, wherein the third̂ insulating layer is a silicon nitride layer.

5. The semiconductor memory device according to claim 1, further comprising a third floating gate provided between the second floating gate and the third insulating layer, the third floating gate including a metal nitride.

6. The semiconductor memory device according to claim 5, wherein the metal nitride is titanium nitride or tantalum nitride.

7. The semiconductor memory device according to claim 1, wherein the third insulating layer is hafnium oxide.

8. The semiconductor memory device according to claim 7, further comprising a fourth insulating layer provided between the third insulating layer and the control gate.

9. The semiconductor memory device according to claim 8, wherein the fourth insulating layer is silicon oxide.

10. The semiconductor memory device according to claim 9, further comprising a fifth insulating layer provided between the fourth insulating layer and the control gate.

11. The semiconductor memory device according to claim 10, wherein the fifth insulating layer is hafnium oxide.

12. The semiconductor memory device according to claim 1, further comprising a barrier metal provided between the third insulating layer and the control gate.

13. The semiconductor memory device according to claim 12, wherein the barrier metal is tungsten nitride.

14. The semiconductor memory device according to claim 8, wherein the fourth insulating layer is provided to be flat on the third insulating layer.

15. The semiconductor memory device according to claim 1, wherein an impurity is doped into the silicon included in the first floating gate.

16. The semiconductor memory device according to claim 1, wherein at least a front surface of the semiconductor substrate is a P-type.

17. The semiconductor memory device according to claim 1, further comprising:
a bit line extending in a first direction; and
a word line extending in a second direction orthogonal to the first direction,
the first insulating layer, the first floating gate, the second insulating layer, the second floating gate, the third insulating layer, and the control gate being provided at a point where the bit line and the word line cross.

18. The semiconductor memory device according to claim 1, comprising:
a first stacked structure including the first insulating layer, the first floating gate, the second insulating layer, the second floating gate, and the third insulating layer, a plurality of the first stacked structures being provided in the first direction; and
a separation region provided between the plurality of first stacked structures.

19. The semiconductor memory device according to claim 18, wherein the control gate is provided commonly for the plurality of first stacked structures.

20. A semiconductor memory device, comprising:
a semiconductor substrate;
a first insulating layer provided on the semiconductor substrate;
a first floating gate provided on the first insulating layer, the first floating gate including silicon;
a second insulating layer provided on the first floating gate;
a ruthenium silicide layer provided on the second insulating layer, the ruthenium silicide layer containing not less than 50 atm % Ru;
a third insulating layer provided on the second floating gate; and
a control gate provided on the third insulating layer.
